(19) United States
(12) Patent Application Publication
(10) Pub. No.: US 2026/0160784 A1
(43) Pub. Date: Jun. 11, 2026

(54) APPARATUS FOR TESTING AN ELECTRONIC DEVICE

(71) Applicant: JCET STATS ChipPAC Korea Limited, Incheon (KR)

(72) Inventors: SunYoung KIM, Gyeonggi-do (KR); YongBeom KIM, Incheon (KR)

(21) Appl. No.: 19/408,477

(22) Filed: Dec. 4, 2025

(30) Foreign Application Priority Data
Dec. 9, 2024 (CN) 202411801052.9

(51) Int. Cl. G01R 1/04; G01R 1/073; G01R 31/28

(52) U.S. Cl. CPC G01R 1/0466; G01R 1/07335; G01R 1/07364; G01R 31/2887

(57) ABSTRACT

An apparatus for testing an electronic device is provided. The apparatus comprises: a test board; a test socket comprising: a socket body having a socket base and a side wall, wherein the side wall has an inner surface inclined relative to the socket base and defining a cavity with an inverted trapezoidal section; and contact pins vertically extending through the socket base; and a device socket lid removably mounted on the test socket, wherein the device socket lid comprises: a pusher portion having a bottom surface and a lateral surface mating with the inner surface of the side wall of the socket body and having a trapezoidal section, such that the pusher portion is substantially accommodated within the cavity of the socket body with the bottom surface aligned with the socket base; and press pins extending from the bottom surface of the pusher portion of the device socket lid.

### TECHNICAL FIELD

The present application relates generally to semiconductor technology, and more particularly, to an apparatus for testing an electronic device.

### BACKGROUND OF THE INVENTION

The semiconductor industry is constantly faced with complex integration challenges as consumers want their electronics to be smaller, faster and higher performance with more and more functionalities packed into a single device. Electronic devices that have undergone complicated processing are subjected to various types of electrical tests for testing their characteristics and for identifying their potential defects.

To this end, a test socket is used to electrically connect metallic wires or contact pads of a test board (for example, a printed circuit board) mounted in test equipment with connectors or terminals of an electronic device to be tested. That is, when an electronic device is tested, the test socket serves as an interface to electrically connect the test board of the test equipment with the electronic device under test. Typically, the test socket may include contact pins which connect the electronic device under test to the test board to transmit signals between the electronic device and the test board during a testing process. A socket lid may be introduced to apply a force to push the electronic device towards the test board. Thus, an electrical connection is set up between the electronic device and the test board through the contact pins for the testing process. However, during the testing process, the socket lid may induce non-uniform stress distribution on the electronic device under test. This may potentially damage the electronic device and adversely impact reliability of the testing environment.

Therefore, a need exists for an apparatus for testing an electronic device.

### SUMMARY OF THE INVENTION

An objective of the present application is to provide an apparatus for testing an electronic device with reduced risks of device damage and improved testing reliability.

According to an aspect of the present application, an apparatus for testing an electronic device is provided. The electronic device comprises a substrate having a set of conductive pads formed on its back surface, and a semiconductor component mounted on a front surface of the substrate and exposed to an external space. The apparatus comprises: a test board; a test socket disposed on the test board, wherein the test socket comprises: a socket body having a socket base for placing the electronic device and a side wall surrounding the socket base, wherein the side wall has an inner surface inclined relative to the socket base and defining a cavity with an inverted trapezoidal section; and contact pins vertically extending through the socket base and movable vertically relative to the socket base, wherein the contact pins are electrically connectable with the set of conductive pads of the electronic device respectively when the electronic device is placed on the socket base; and a device socket lid removably mounted on the test socket, wherein the device socket lid comprises: a top cover portion operably supported on the side wall of the socket body; a pusher portion extending downward from the top cover portion, and having a bottom surface and a lateral surface mating with the inner surface of the side wall of the socket body and having a trapezoidal section, such that the pusher portion is substantially accommodated within the cavity of the socket body with the bottom surface aligned with the socket base, when the device socket lid is mounted on the test socket; and press pins extending from the bottom surface of the pusher portion of the device socket lid, wherein the press pins are configured to press the substrate of the electronic device downward against the test board through the contact pins of the test socket to set up an electrical connection between the electronic device and the test board, when the device socket lid is mounted on the test socket.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate an apparatus for testing an electronic device according to a first embodiment of the present application.

FIGS. 2A to 2C illustrate an apparatus for testing an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, when an electronic device is being tested, a test socket serves as an interface to electrically connect a test board with the electronic device under test. A socket lid may be introduced to apply a force to push the electronic device towards the test board to set up an electrical connection between the electronic device and the test board through contact pins of the test socket for the testing process. In a conventional testing environment, the socket lid may have a press head which is in contact with the electronic device when the electronic device is pressed by the socket lid. However, when the electronic device is pressed by the socket lid, stress may concentrate at specific points or areas of the electronic device, which is usually determined by a contact surface of the press head. For example, the press head may only cover a portion of the electronic device, which may induce non-uniform stress distribution to the electronic device. In some cases where the electronic device is an open-top electronic device without a top encapsulant layer, semiconductor components, which are generally made of silicon or similar fragile materials, of the electronic device may be exposed to an external space and in direct contact with the press head. Therefore, the non-uniform stress distribution created by the press head may potentially induce severe damages to the electronic device under test.

To address the above issue, an apparatus for testing an electronic device is provided. The electronic device includes a semiconductor component which is exposed to an external space. The apparatus includes a test board, a test socket including a plurality of contact pins, and a device socket lid. The test socket further includes an inclined inner surface and defines a cavity with an inverted trapezoidal section. Accordingly, the device socket lid includes a pusher portion having a lateral surface mating with the inner surface of the test socket and having a trapezoidal section. Additionally, the device socket lid also includes press pins extending from the bottom surface of the pusher portion. When the electronic device is being tested, the electronic device is pressed against the test board by the press pins of the device socket lid to set up an electrical connection between the electronic device and the test board through the contact pins. Since the pusher portion has an inclined lateral surface, a bottom surface of the pusher portion may have an increased surface area which may be aligned with a larger surface area of the electronic device. Thus, when the electronic device is pressed by the device socket lid, the stress generated in the electronic device may have a more uniform distribution across almost an entirety of the electronic device. Furthermore, the press pins of the device socket lid may create a gap between the electronic device and the pusher portion to avoid direct contact between the semiconductor component and the pusher portion. Therefore, the apparatus may greatly reduce potential damages to the electronic device especially the semiconductor component during the testing process and may also improve the testing reliability.

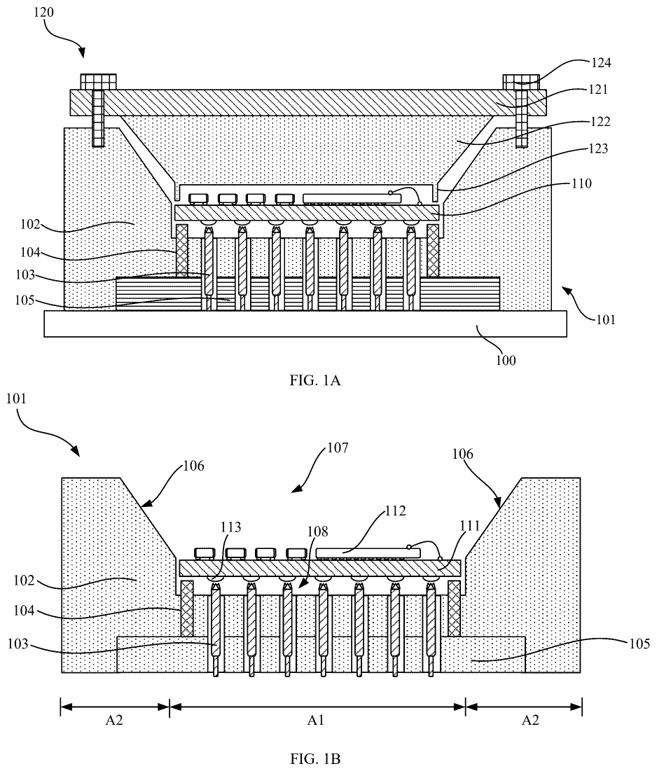

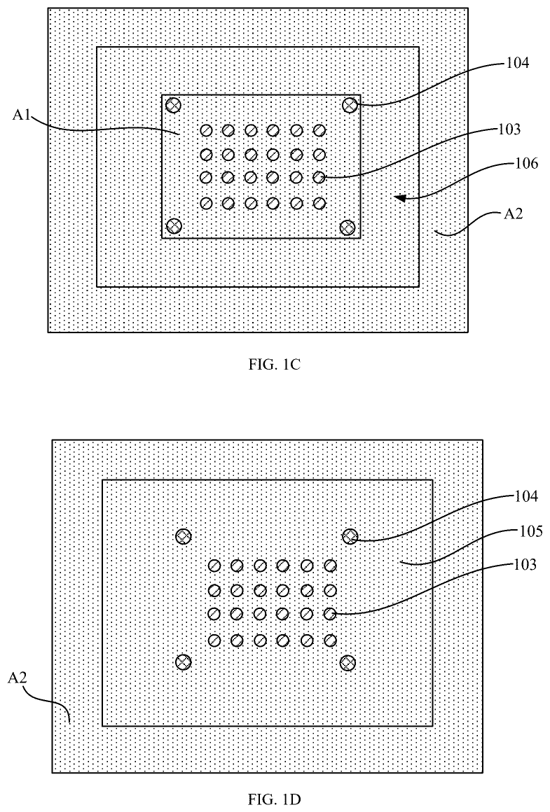

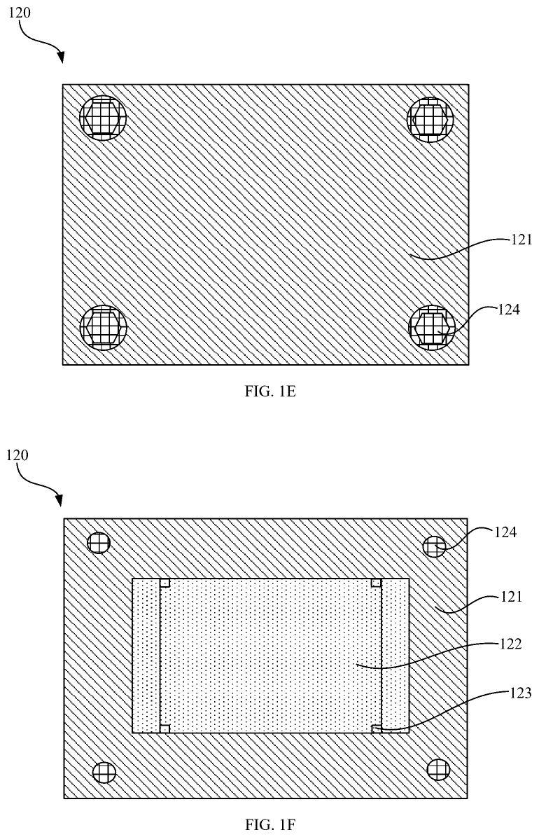

FIGS. 1A to 1F illustrate an apparatus for testing an electronic device according to a first embodiment of the present application. In particular, FIG. 1A illustrates a sectional view of the apparatus. FIG. 1B illustrates more details of a test socket of the apparatus shown in FIG. 1A with the electronic device mounted on the test socket. FIG. 1C illustrates a top view of the test socket shown in FIG. 1B, and FIG. 1D illustrates a bottom view of the test socket shown in FIG. 1B. FIG. 1E illustrates a top view of a device socket lid shown in FIG. 1A, and FIG. 1F illustrates a bottom view of the device socket lid shown in FIG. 1A.

As shown in FIG. 1A, the apparatus includes a test board 100, a test socket 101 disposed on the test board 100, and a device socket lid 120 removably mounted on the test socket 101. An electronic device 110 is placed on the test socket 101 for testing its characteristics and for identifying its potential defects. During a testing process of the electronic device 110, the electronic device 110 is pressed against the test board 100 by the device socket lid 120 to set up an electrical connection between the electronic device 110 and the test board 100 for the testing process.

In some embodiments, the test board 100 serves as a base of the apparatus, which can be electrically connected with an electronic device 110 when it is being tested. Also, the test board 100 is electrically coupled to test equipment such as a multimeter with or without a signal generator for testing the electronic device 110. In some embodiments, the test board 100 includes a device placement region for placing a testing fixture (e.g., a test socket 101) and the electronic device 110 under test. Furthermore, the test board 100 includes a test region where test equipment can be placed and/or connected such that the test equipment can be electrically coupled with the electronic device 110. In some embodiments, the device placement region may be a central zone of the test board 100, and the test region may be a peripheral zone of the test board 100. Alternatively, the test region may be at a back surface of the test board 100 as long as it is convenient for the test tool to get access to. Furthermore, a signaling route such as a metallic wire may be included within the test board 100, which is used for transmitting signals between the electronic device 110 and the test equipment. For example, during the testing of the electronic device 110, the signaling route may be coupled with the signal generator of the test equipment to receive and apply to the electronic device 110 a test signal. In some embodiments, the signaling route may have a respective layout corresponding to a layout of the electronic device 110, for example, a specific length corresponding to a size of the electronic device 110. However, the configuration of the test board 100 and the test equipment is exemplary and not mandatory. In some alternative embodiment, the test board 100 may integrate within itself all the functions such as signal generation and electrical measurement which are desired for the testing of the electronic device 110, and thus no further test equipment is needed.

The detailed structures of the test socket 101 and the electronic device 110 under test are illustrated in FIGS. 1B to 1D. As shown in FIG. 1B, the test socket 101 includes a socket body 102, which is disposed on the test board 100, or particularly, on the device placement region. The socket body 102 has a socket base A1 and a side wall A2 surrounding the socket base A1. In some embodiments, the socket base A1 may be a central portion of the socket body 102, and the side wall A2 may be a peripheral portion of the socket body 102. Also, the socket body 102 may have a rectangular layout, for example. During the testing process, the electronic device 110 is placed on a front surface of the socket base A1. The side wall A2 may have a height greater than a total height of the socket base A1 and the electronic device 110, which surrounds the electronic device 110 when it is placed on the socket base A1. In addition, the side wall A2 has an inner surface 106 inclined relative to the socket base A1, and the inclined inner surface 106 defines a cavity 107 with an inverted trapezoidal section above the socket base A1. In other words, a size of the cavity 107 decreases gradually from a top portion of the inner surface 106 to its bottom portion, thus forming the inverted trapezoidal shaped cavity 107. The cavity 107 exposes the front surface of the socket base A1, and also accommodates the electronic device 110 therewithin. In some embodiments, the side wall A2 also includes a flat surface extending from the inclined inner surface 106 to its external lateral surface, which is used for placing a portion of the device socket lid 120. Moreover, the inclined inner surface 106 of the side wall A2 mates with an external surface of the device socket lid 120, which will be elaborated later. In some embodiments, an angle between the inner surface 106 of the side wall A2 and the front surface of the socket base A1 may be greater than 95 degrees, or preferably between 105 to 135 degrees.

Furthermore, in some embodiments, the test socket 101 may also include a bottom plate 105, which is embedded within the socket base A1 and at least a part of the side wall A2. In the embodiment shown in FIGS. 1A to 1D, the socket base A1 and the side wall A2 may be formed as an integral piece. In some other embodiments, the socket base A1 and the side wall A2 may be provided separately and be assembled together before the testing process.

As shown in FIG. 1B, the electronic device 110 is an open-top electronic device 110, which includes a substrate 111 and a semiconductor component 112 mounted on a front surface of the substrate 111. In some embodiments, the electronic device 110 may include various types of electronic modules, such as a Radio Frequency (RF) device, a semiconductor chip, a resistor, a capacitor, a System in Package (SiP) module or other large-sized devices with complex functionalities. The semiconductor component 112 is exposed to an external space without capsulation on the substrate 111. In this embodiment, the electronic device 110 is being tested when the semiconductor component 112 is not encapsulated for a more accurate measurement of electrical characteristics, for example. The semiconductor component 112 and the substrate 111 may or may not be encapsulated after the testing process. In some embodiments, the electronic device 110 may include more than one semiconductor components 112 with various layouts and structures. Furthermore, the substrate 111 also has a set of conductive pads formed on its back surface, and a plurality of solder bumps 113 may further be formed on the set of conductive pads to provide an electrical connection between the electronic device 110 and the test socket 101.

In some embodiments such as the embodiment shown in FIG. 1B, the socket base A1 further includes a recess 108 on its front surface. The recess 108 reduces a height of the socket base A1. The recess 108 is right below the cavity 107 and is connected with the cavity 107. When the electronic device 110 is placed onto the socket base A1, at least a portion of the substrate 111 may be received within the recess 108. In some embodiments, the recess 108 may have a side surface perpendicular to the front surface of the socket base A1. The recess 108 may have a size slightly larger than that of the substrate 111. In this way, when the substrate 111 is received within the recess 108, a movement of the substrate 111 in a horizontal direction of the socket base A1 can be prevented by the side surface of the recess 108 to fix the substrate 111 in place during the testing process. In some other embodiments, the socket base A1 may not include the recess 108. In other words, the inverted trapezoidal shaped cavity 107 may be closed by the front surface of the socket base A1.

Furthermore, as shown in FIGS. 1B to 1D, the socket base A1 may have a plurality of through holes extending from its front surface to its back surface. The socket base A1 includes a plurality of contact pins 103 vertically extending through the socket base A1 and accommodated within the plurality of through holes, respectively. The contact pins 103 are movable vertically relative to the socket base A1. In some embodiments, the contact pins 103 may extend into the recess 108 or/and the cavity 107 of the test socket 101. When the electronic device 110 is placed onto the socket base A1, each of the conductive pads on the back surface of the substrate 111 can be aligned with one of the contact pins 103. During the testing process of the electronic device 110, the contact pins 103 can establish an elastic and electrical connection between the electronic device 110 and the test board 100. Top ends and bottom ends of the contact pins 103 may be exposed from the front surface and the bottom surface of the socket base A1 respectively to allow for convenient connections with the electronic device 110 and the test board 100 respectively. In some embodiments, the test board 100 may include a plurality of device contact pads in the device placement region which are used for coupling the contact pins 103.

In some embodiments, the contact pins 103 include pogo pins. Each pogo pin 103 includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with the top contactor at its top end, and can be in contact with the bottom contactor at its bottom end. As such, the pogo pins 103 can be movable vertically relative to the socket base A1 with the coil spring providing an elastic connection between the electronic device 110 and the test board 100. With these configurations, when the electronic device 110 is being tested, the top contactors of the pogo pins 103 can be in contact with conductive pads or solder bumps 113 of the electronic device 110, and the bottom contactors can be in contact with the device contact pads in the device placement region. Additionally, the top contactors and the bottom contactors are exposed from the front surface and the back surface of the socket base A1. When the electronic device 110 is being tested, the contact pins 103 may be pressed against the test board 100 to set up a reliable electrical connection between the electronic device 110 and the test board 100, which builds a test environment or system to test the electronic device 110. In some other embodiments, the contact pins 103 may include other types of elastic connectors, such as elastic conductive pillars.

Moreover, the apparatus further includes a device socket lid 120 removably mounted on the test socket 101. During the testing process, the device socket lid 120 is used to press the electronic device 110 against the test board 100 to establish an electrical connection between the electronic device 110 and the test board 100. Here, at least a portion of the device socket lid 120 is inserted within the cavity 107 of the test socket 101.

Referring to FIG. 1A in conjunction with FIGS. 1E and 1F, the device socket lid 120 includes a top cover portion 121, a pusher portion 122 extending downward from the top cover portion 121, and press pins 123 extending from the bottom surface of the pusher portion 122. During the testing process, the top cover portion 121 is supported on the flat top surface of the side wall A2 of the socket body 102, such that a substantial part of the pusher portion 122 and the press pins 123 of the device socket lid 120 can be accommodated within the cavity 107 of the test socket 101. The pusher portion 122 has a configuration such as a shape and size mating with the cavity 107. To be more specific, the pusher portion 122 has a bottom surface, and a lateral surface inclined relative to the bottom surface which mates with the inner surface 106 of the side wall A2 of the socket body 102. That is, the pusher portion 122 also has an inverted trapezoidal section, which is similar to that of the cavity 107 of the socket body 102. The size of the pusher portion 122 decreases gradually from its top surface to its bottom surface, thus forming the inverted trapezoidal shaped section of pusher portion 122. In some embodiments, the section of the pusher portion 122 may be an isosceles trapezoid. In some alternative embodiments, the section of the pusher portion may be a scalene trapezoid.

When the device socket lid 120 is inserted into the cavity 107 of the socket body 102, the bottom portion of the pusher portion 122 with a smaller size may enter into the cavity 107 easily. When the pusher portion 122 moves deeper within the cavity 107, the pusher portion 122 may displace horizontally with respect to the socket body 102 due to the sliding fit between the lateral surface of the pusher portion 122 and the inner surface 106 of the side wall A2, resulting in alignment between the bottom surface of the pusher portion 122 with the substrate 111 of the electronic device 110. This self-alignment characteristic of the pusher portion 122 within the cavity 107 benefits from the gradually shrinking inner surface 106 of the side wall A2 and the gradually shrinking lateral surface of the pusher portion 122. Therefore, the pusher portion 122 may be aligned accurately with the substrate 111 of the electronic device 110 with a simpler and more convenient alignment procedure. In some embodiments, the lateral surface of the pusher portion 122 may be parallel to the inner surface 106 of the cavity 107 of the socket body 102, with a minor gap therebetween, which facilitates the mounting process of the device socket lid 120 onto the test socket 101. In some other embodiments, an inclined angle of the lateral surface of the pusher portion 122 relative to the front surface of the socket base A1 may be slightly different from that of the inner surface 106 of the cavity 107, as long as the device socket lid 120 can still be accommodated within the cavity 107 to move downward towards the electronic device 110. Additionally, the bottom surface of the pusher portion 122 is aligned with the socket base A1 when the device socket lid 120 is mounted on the test socket 101. Since the pusher portion 122 has the inclined lateral surface and the trapezoidal section, a bottom surface of the pusher portion 122 may have an increased surface area which may be aligned with a larger surface area of the electronic device 110. As shown in FIG. 1A, the bottom surface of the pusher portion 122 covers almost an entirety of the substrate 111 of the electronic device 110.

As shown in FIGS. 1E and 1F, the top cover portion 121 and the pusher portion 122 of the device socket lid 120 may have a rectangular layout, which is similar to a layout of the substrate 111 of the electronic device 110. In some other embodiments, the top cover portion 121 and the pusher portion 122 may have other layouts, as long as the pusher portion 122 can be aligned with the substrate 111 of the electronic device 110.

Furthermore, during the testing process, the press pins 123 extending from the bottom surface of the pusher portion 122 can press the substrate 111 of the electronic device 110 downward against the test board 100. In some embodiments, the press pins 123 are individual pillars extending from a periphery of the bottom surface of the pusher portion 122, such as at four corners of the bottom surface. The press pins 123 are aligned with or close to a periphery of the substrate 111 of the electronic device 110. In this way, during the testing process, the electronic device 110 can be pressed against the test board 100 by the press pins 123 to set up an electrical connection between the electronic device 110 and the test board 100 through the contact pins 103 for testing the electronic device 110. Furthermore, the press pins 123 may have a height relative to the bottom surface of the pusher portion 122 greater than that of the semiconductor component 112 relative to a front surface of the substrate 111. Therefore, when the substrate 111 is pressed against the test board 100 by the press pins 123, a gap is created between the semiconductor component 112 and the pusher portion 122 to avoid direct contact therebetween. The gap can protect the semiconductor component 112 from potential damages due to a strike by the pusher portion 122. Also, the press pins 123 may be sized to have a predetermined height to make sure that the contact pins 103 can be pressed against the test board 100 for a predetermined distance to maintain proper resistance of the test socket 101.

The device socket lid 120 may provide several advantages for the testing process compared with conventional socket designs. In this embodiment, the inclined lateral surface of the pusher portion 122 results in an increased surface area which may be aligned with a larger surface area of the substrate 111. For example, the bottom surface of the pusher portion 122 may cover almost an entirety of the substrate 111. Thus, the press pins 123 extending from the periphery of the bottom surface of the pusher portion 122 can be aligned with the periphery of the substrate 111. When an external force is applied to the device socket lid 120 to press the substrate 111, the external force may be transferred to the press pins 123, and finally be distributed uniformly across each of the press pins 123. Furthermore, the stress applied to the substrate 111 by the press pins 123 may be distributed across the whole substrate 111 uniformly rather than concentrating at specific points or areas of the electronic device 110. Therefore, the substrate 111 and the contact pins 103 below the substrate 111 may be pressed against the test board 100 in a more uniform and balanced manner. Based on this, each of the contact pins 103 under the substrate 111 can be exposed to a more uniform stress regardless of its location or arrangement, and in turn, exert a uniform counter-acting force to the substrate 111, thereby reducing potential damages to the electronic device 110. In addition, with the uniform distributed stress, each of the solder bumps 113 and the respective one of the contact pins 103 may be in close contact with each other, thus forming a reliable connection therebetween during the testing process.

In some other embodiments, the press pins 123 may have another layout such as an elongated bar, which may be arranged at four edges of the bottom surface of the pusher portion 122. This provides a larger contact area between the press pins 123 and the substrate 111, thus resulting in a more uniform and balanced distribution of stress to the whole substrate 111. In some alternative embodiments, apart from the press pins 123 at the periphery of the pusher portion 122, the press pins 123 may also be arranged at or close to a central region of the bottom surface of the pusher portion 122 to provide additional stress, as long as the press pins 123 are not in contact with the semiconductor component 112. It can be appreciated that the press pins 123 may have other layouts and arrangements according to the layout of the substrate 111 and the semiconductor component 112.

In some embodiments, the press pins 123 and the pusher portion 122 may be formed as an integral piece. In some other embodiments, the press pins 123 may be separated from the pusher portion 122 and be assembled with the pusher portion 122 before the testing process. In this case, the press pins 123 with a specific layout and height may be selected and mounted onto specific locations on the bottom surface of the pusher portion 122 to achieve desired configurations according to various layouts of the electronic device 110. Fasteners may be set on the bottom surface of the pusher portion 122 for securing the press pins 123 onto the pusher portion 122. Alternatively, the bottom surface of the pusher portion 122 may include locating slots for receiving the press pins 123. In some additional embodiments, the height of the press pins 123 may be adjustable by extending and retracting the press pins 123 until a desired height or length of the press pins 123 is achieved.

Furthermore, still referring to FIG. 1A and FIGS. 1E and 1F, the device socket lid 120 further includes a plurality of fasteners 124 removably mounted between the top cover portion 121 and the side wall A2 of the test socket 101. For example, the fasteners 124 may be arranged at four corners of the top cover portion 121. In some embodiments, the fasteners 124 may be screws. When the electronic device 110 has been pressed against the test board 100 by the press pins 123, the fasteners 124 are further fixed to the top cover portion 121 to secure the top cover portion 121 with the side wall A2 of the socket body 102. As such, the device socket lid 120 may apply a stable, consistent and controllable stress to the electronic device 110 during the testing process.

In addition, referring back to FIGS. 1A to 1D, the electronic device 110 is directly placed onto the contact pins 103. Thus, the stress applied by the device socket lid 120 may be transferred to the electronic device 110 in a more direct and sufficient manner. Referring back to FIGS. 1A to 1D, the test socket 101 further includes at least one stopper 104 each extending upward from the socket base A1 into the cavity 107 or recess 108 of the test socket 101. The at least one stopper 104 is engageable with the back surface of the substrate 111. When the substrate 111 is pressed towards the test board 100 by the press pins 123, the at least one stopper 104 may be in contact with the bottom surface of the substrate 111 at some point. Therefore, the at least one stopper 104 may prevent the substrate 111 from moving further towards the test board 100. In this way, the at least one stopper 104 may protect the contact pins 103 from being applied with an excessive force, and may also protect the electronic device 110 from potential device damages caused by over-stroking of the contact pins 103. Also, the stopper(s) 104 may allow for a consistent resistance of the test socket 101 while a smaller external force is required to mount the electronic device 110 onto the test socket 101. It should be noted that a height of the stopper(s) 104 relative to the front surface of the socket base A1 should be smaller than a total height of solder bumps 113 and exposed portions of the contact pins 103, such that the stopper(s) 104 may not be an obstacle when the electronic device 110 is being pressed against the test board 100 before an electrical connection is established between the electronic device 110 and the contact pins 103.

In some embodiments, as shown in FIGS. 1C and 1D, the test socket 101 may include four stoppers 104, which are arranged at four corners of the socket base A1, to provide a balanced support to the substrate 111. The stoppers 104 may extend through the socket base A1, be exposed from the front surface of the socket base A1 and a bottom surface of the socket base A1 (i.e., a bottom surface of the bottom plate 105). In some other embodiments, the apparatus may include more or fewer stoppers 104 according to the layout of the electronic device 110. In addition, the stopper(s) 104 may be formed as individual components or an integral piece such as a continuous ring. In some preferred embodiments, the stopper(s) 104 may be aligned with the periphery of the substrate 111 to release the stress applied by the press pins 123 more directly.

After the electronic device 110 is pressed against the test board 100 by the device socket lid 120 to set up an electrical connection between the electronic device 110 and the test board 100, the electrical characteristics of the electronic device 110 may be tested. In some preferred embodiments, the device socket lid 120 may further include at least one through hole which allows for easy connection of the electronic device 110 to external test points of test equipment, as will be elaborated below.

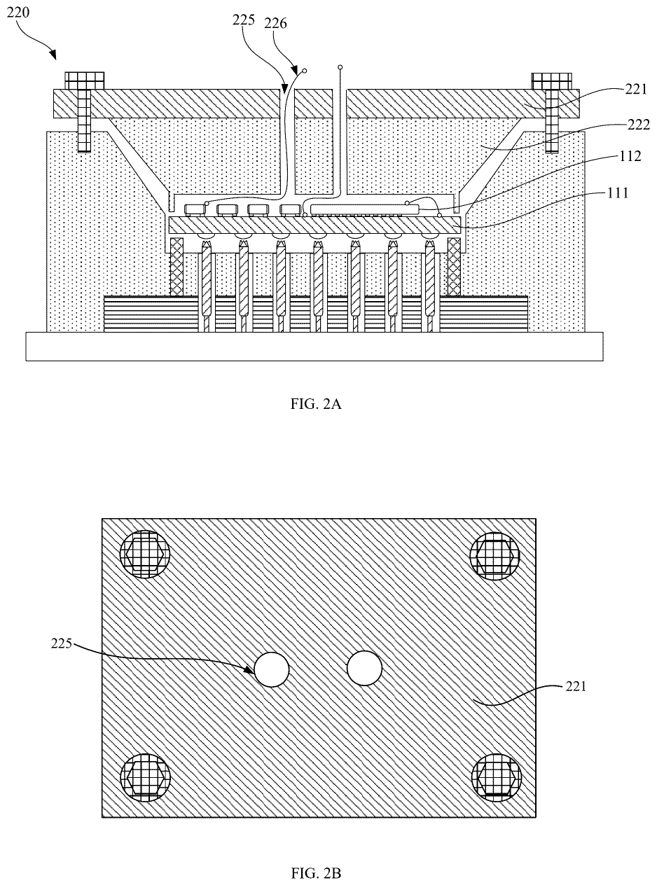

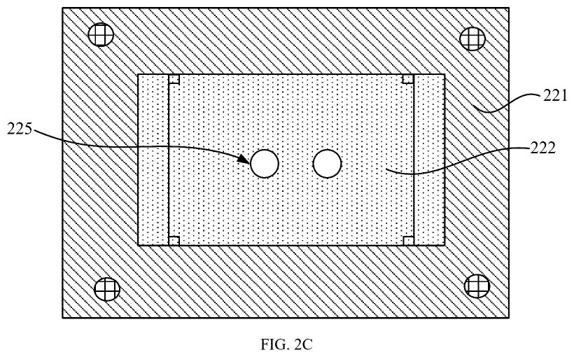

FIGS. 2A to 2C illustrate an apparatus for testing an electronic device according to a second embodiment of the present application. In particular, FIG. 2A illustrates a sectional view of the apparatus. FIG. 2B illustrates a top view of a device socket lid shown in FIG. 2A, and FIG. 2C illustrates a bottom view of the device socket lid shown in FIG. 2A.

The apparatus illustrated in FIGS. 2A to 2C includes parts and structures similar as the apparatus shown in FIGS. 1A to 1F, except that a device socket lid 220 included in the apparatus in FIGS. 2A to 2C has at least one through hole 225, which is not included within the device socket lid 120 illustrated in FIG. 1A and FIGS. 1E and 1F.

As shown in FIGS. 2A to 2C, the device socket lid 220 further includes at least one through hole 225 each passing through the pusher portion 222 and the top cover portion 221. Therefore, certain components of the electronic device, such as the substrate 111 and/or the semiconductor component 112, can be accessed directly from an external space through the at least one through holes 225. Furthermore, a connection wire 226 is extending through one of the through holes 225, with one end connected with the electronic device and the other end connected with an external test point. To be more specific, the connection wire 226 may be a flexible wire, such as a jumper wire which can pass through the through hole 225 and be bended as desired to establish a connection with the electronic device. In some embodiments, the connection wire 226 is connected with the electronic device on its front surface, for example, on a front surface of the semiconductor component 112 or on a front surface of the substrate 111. During the testing process, the connection wire 226 may be used to set up an easy and efficient connection between the electronic device and the external test points of test equipment, which simplifies a wiring arrangement and improves flexibility in a testing process.

In some embodiments, the apparatus may include two through holes 225 arranged in a central region of the device socket lid 220. Accordingly, two connection wires 226 may be accommodated within the through holes 225 respectively to connect different semiconductor component(s) 112 and/or the substrate 111 with respective external test points such as probes of the external test equipment. In some other embodiments, the apparatus may include more or fewer through holes 225. It can also be appreciated that the through hole(s) may be arranged at designed positions, such as at a periphery of the device socket lid 220, according to a layout of the electronic device and/or a desired wiring arrangement between the electronic device and the external test equipment.

While the exemplary apparatus for testing an electronic device of the present application is described in conjunction with corresponding figures, it will be understood by those skilled in the art that modifications and adaptations to the apparatus may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for testing an electronic device, wherein the electronic device comprises a substrate having a set of conductive pads formed on its back surface, and a semiconductor component mounted on a front surface of the substrate and exposed to an external space; and
wherein the apparatus comprises:
a test board;
a test socket disposed on the test board, wherein the test socket comprises:
a socket body having a socket base for placing the electronic device and a side wall surrounding the socket base, wherein the side wall has an inner surface inclined relative to the socket base and defining a cavity with an inverted trapezoidal section; and
contact pins vertically extending through the socket base and movable vertically relative to the socket base, wherein the contact pins are electrically connectable with the set of conductive pads of the electronic device respectively when the electronic device is placed on the socket base; and
a device socket lid removably mounted on the test socket, wherein the device socket lid comprises:
a top cover portion operably supported on the side wall of the socket body;
a pusher portion extending downward from the top cover portion, and having a bottom surface and a lateral surface mating with the inner surface of the side wall of the socket body and having a trapezoidal section, such that the pusher portion is substantially accommodated within the cavity of the socket body with the bottom surface aligned with the socket base, when the device socket lid is mounted on the test socket; and
press pins extending from the bottom surface of the pusher portion of the device socket lid, wherein the press pins are configured to press the substrate of the electronic device downward against the test board through the contact pins of the test socket to set up an electrical connection between the electronic device and the test board, when the device socket lid is mounted on the test socket.

2. The apparatus of claim 1, wherein the press pins extend from a periphery of the bottom surface of the pusher portion.

3. The apparatus of claim 2, wherein the press pins are aligned with a periphery of the substrate of the electronic device, when the device socket lid is mounted on the test socket.

4. The apparatus of claim 2, wherein the press pins have a height relative to the bottom surface of the pusher portion greater than a height of the semiconductor component relative to a front surface of the substrate to avoid direct contact between the semiconductor component and the pusher portion when the device socket lid is mounted on the test socket.

5. The apparatus of claim 1, wherein the device socket lid is not in contact with the semiconductor component when the substrate of the electronic device is pressed against the test board by the press pins.

6. The apparatus of claim 1, wherein the test socket further comprises:
at least one stopper each extending upward from the socket base and engageable with the back surface of the substrate when the substrate of the electronic device is pressed against the test board by the press pins.

7. The apparatus of claim 1, wherein the socket base further comprises a recess on its front surface, and the recess is connected to the cavity and configured for accommodating at least a portion of the substrate of the electronic device to prevent a movement of the electronic device in a horizontal direction when the electronic device is placed on the socket base.

8. The apparatus of claim 1, wherein the device socket lid further comprises:
at least one through hole each passing through the pusher portion and the top cover portion and configured for receiving a connection wire.

9. The apparatus of claim 8, wherein the connection wire comprises a jumper wire which is connectable with the electronic device.

10. The apparatus of claim 1, wherein the device socket lid further comprises: a plurality of fasteners removably mounted between the top cover portion and the side wall of the test socket to secure the top cover portion with the side wall of the socket body when the electronic device is pressed against the test board by the press pins.
